(19) United States
(12) Patent Application Publication
(10) Pub. No.: US 2015/0140786 A1
(43) Pub. Date: May 21, 2015

(54) SUBSTRATE PROCESSING DEVICE AND SUBSTRATE PROCESSING METHOD

(71) Applicant: JUSUNG ENGINEERING CO., LTD., Gwangiu-si, Gyeonggi-do (KR)

(72) Inventor: Jae Chan Kwak, Yongin-si (KR)

(73) Assignee: Jusung Engineering Co., Ltd., Gwangju-si, Gyeonggi-do (KR)

(21) Appl. No.: 14/404,446

(22) PCT Filed: May 28, 2013
(86) PCT No.: PCT/KR2013/004677

§ 371 Date: Nov. 26, 2014

(30) Foreign Application Priority Data
May 29, 2012 (KR) 10-2012-0057022

(51) Int. Cl. C23C 16/455; C23C 16/458; H01L 21/02; C23C 16/50

(52) U.S. Cl. CPC C23C 16/45544; C23C 16/50; C23C 16/4584; H01L 21/0262
USPC 438/478; 118/728; 118/723 E

(57) ABSTRACT

Disclosed is an apparatus and method for processing substrate, which facilitates to prevent a substrate form being damaged, wherein the apparatus comprises a process chamber; a substrate supporter for supporting at least one of substrates, wherein the substrate supporter is provided in the bottom of the process chamber; a chamber lid confronting with the substrate supporter, the chamber lid for covering an upper side of the process chamber; and a gas distributing part provided in the chamber lid, wherein the gas distributing part distributes source gas to a source gas distribution area on the substrate supporter, distributes reactant gas to a reactant gas distribution area which is separated from the source gas distribution area, and distributes purge gas to a space between the source gas distribution area and the reactant gas distribution area.

### CROSS REFERENCE TO RELATED APPLICATIONS

This application claims the benefit of the Korean Patent Application No. 10-2012-0057022 filed on May 29, 2012, which is hereby incorporated by reference as if fully set forth herein.

### BACKGROUND

1. Field of the Invention

The present invention relates to an apparatus and method of processing substrate which deposits a thin film on a substrate.

2. Discussion of the Related Art

Generally, in order to manufacture a solar cell, a semiconductor device and a flat panel display device, it is necessary to form a predetermined thin film layer, a thin film circuit pattern or an optical pattern on a surface of a substrate. Thus, a semiconductor manufacturing process may be carried out, for example, a thin film deposition process of depositing a thin film of a predetermined material on a substrate, a photo process of selectively exposing the thin film by the use of photosensitive material, and an etching process of forming a pattern by selectively removing an exposed portion of the thin film.

The semiconductor manufacturing process is performed inside a substrate processing apparatus designed to be suitable for optimal circumstances. Recently, a substrate processing apparatus using plasma is generally used to carry out a deposition or etching process.

This semiconductor manufacturing process using plasma may be a PECVD (Plasma Enhanced Chemical Vapor Deposition) apparatus for forming a thin film, and a plasma etching apparatus for etching and patterning the thin film.

FIG. 1 illustrates a substrate processing apparatus according to the related art.

Referring to FIG. 1, the substrate processing apparatus according to the related art may include a chamber 10, a plasma electrode 20, a susceptor 30, and a gas distributing means 40.

The chamber 10 provides a reaction space for substrate processing. In this case, a predetermined portion of a bottom surface of the chamber 10 is communicated with an exhaust pipe 12 for discharging gas from the reaction space.

The plasma electrode 20 is provided on the chamber 10 so as to seal the reaction space.

One side of the plasma electrode 20 is electrically connected with a RF (Radio Frequency) power source 24 through a matching member 22. The RF power source 24 generates RF power, and supplies the generated RF power to the plasma electrode 20.

Also, a central portion of the plasma electrode 20 is communicated with a gas supply pipe 26 of supplying source gas for the substrate processing.

The matching member 22 is connected between the plasma electrode 20 and the RF power source 24, to thereby match load impedance and source impedance of the RF power supplied from the RF power source 24 to the plasma electrode 20.

The susceptor 30 is provided inside the chamber 10, and the susceptor 30 supports a plurality of substrates W loaded from the external. The susceptor 30 corresponds to an opposite electrode in opposite to the plasma electrode 20, and the susceptor 30 is electrically grounded by an elevating axis 32 for elevating the susceptor 30.

The elevating axis 32 is moved up and down by an elevating apparatus (not shown). In this case, the elevating axis 32 is surrounded by a bellows 34 for sealing the elevating axis 32 and the bottom surface of the chamber 10.

The gas distributing means 40 is provided below the plasma electrode 20, wherein the gas distributing means 40 confronts with the susceptor 30. In this case, a gas diffusion space 42 is formed between the gas distributing means 40 and the plasma electrode 20. Inside the gas diffusion space 42, the source gas supplied from the gas supply pipe 26 penetrating through the plasma electrode 20 is diffused. The gas distributing means 40 uniformly distributes the source gas to the entire area of the reaction space through a plurality of gas distributing holes 44 being communicated with the gas diffusion space 42.

In case of the substrate processing apparatus according to the related art, after the substrate (W) is loaded onto the susceptor 30, the predetermined source gas is distributed to the reaction space of the chamber 10, and the RF power is supplied to the plasma electrode 20 so as to form the plasma in the reaction space between the susceptor 30 and the gas distributing means 40, to thereby deposit a source material of the source gas on the substrate (W) by the use of plasma.

However, the substrate processing apparatus according to the related art may have the following problems.

Also, a density of the plasma formed on the entire area of the susceptor 30 is not uniform so that a uniformity of the thin film material deposited on the substrate (W) is deteriorated, and it is difficult to control quality of the thin film.

Furthermore, since the plasma is formed on the entire area of the susceptor 30, a thickness of the source material deposited on the chamber 10 as well as a thickness of the source material deposited on the substrate (W) may be rapidly increased so that a cleaning cycle of the chamber 10 is shortened.

### SUMMARY

Accordingly, the present invention is directed to an apparatus and method of processing substrate that substantially obviates one or more problems due to limitations and disadvantages of the related art.

An aspect of the present invention is to provide an apparatus and method of processing substrate, which spatially separates source gas and reactant gas to be distributed to a substrate so as to realize a good deposition uniformity in a thin film deposited on the substrate, and to improve the yield.

Additional advantages and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these and other advantages and in accordance with the purpose of the invention, as embodied and broadly described herein, there is provided a substrate processing apparatus comprising: a process chamber; a substrate supporter for supporting at least one of substrates, wherein the substrate supporter is provided in the bottom of the process chamber; a chamber lid confronting with the substrate supporter, the chamber lid for covering an upper side of the process chamber; and a gas distributing part provided in the chamber lid, wherein the gas distributing part distributes source gas to a source gas distribution area on the substrate supporter, distributes reactant gas to a reactant gas distribution area which is separated from the source gas distribution area, and distributes purge gas to a space between the source gas distribution area and the reactant gas distribution area.

In another aspect of the present invention, there is provided a substrate processing apparatus comprising: a process chamber; a substrate supporter for supporting at least one of substrates, wherein the substrate supporter is provided in the bottom of the process chamber; a chamber lid confronting with the substrate supporter, the chamber lid for covering an upper side of the process chamber; a gas distributing part for separately distributing source gas and reactant gas to different areas of the substrate supporter, wherein the gas distributing part is formed in the chamber lid; and a gas pumping part for separating the source gas in the circumference of the source gas distribution area from the reactant gas in the circumference of the reactant gas distribution area, and pumping the separated source gas and reactant gas out of the process chamber, wherein the gas pumping part is formed in the chamber lid.

In another aspect of the present invention, there is provided a substrate processing method comprising: loading at least one substrate onto a substrate supporter provided inside a process chamber; distributing source gas to a source gas distribution area of the substrate supporter, distributing reactant gas to a reactant gas distribution area which is separated from the source gas distribution area, and distributing purge gas to a space between the source gas distribution area and the reactant gas distribution area; and rotating the substrate supporter with at least one substrate loaded thereonto.

In a further aspect of the present invention, there is provided a substrate processing method comprising: loading at least one substrate onto a substrate supporter provided inside a process chamber; separately distributing source gas and reactant gas to different areas of the substrate supporter; separating the source gas in the circumference of a source gas distribution area to be supplied with the source gas from reactant gas in the circumference of a reactant gas distribution area to be supplied with the reactant gas, and pumping the separated source gas and reactant gas out of the process chamber; and rotating the substrate supporter with at least one substrate loaded thereonto.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a substrate processing apparatus according to the related art;

FIG. 2 is a perspective view illustrating a substrate processing apparatus according to the first embodiment of the present invention;

FIG. 3 is a plane view illustrating a chamber lid shown in FIG. 2;

FIG. 4 is a cross sectional view illustrating a chamber lid along I-I′ of FIG. 3;

FIG. 5 is a cross sectional view illustrating a chamber lid along II-II′ of FIG. 3;

FIG. 6 is a plane view illustrating a gas distribution area and a gas pumping area defined on a substrate supporter shown in FIG. 2;

FIG. 7 illustrates a substrate processing apparatus according to the second embodiment of the present invention;

FIG. 8 is a plane view illustrating a gas distribution area and a gas pumping area defined on a substrate supporter shown in FIG. 2;

FIG. 9 illustrates a substrate processing apparatus according to the third embodiment of the present invention;

FIG. 10 is a cross sectional view illustrating a pair of source gas distribution modules shown in FIG. 9;

FIG. 11 illustrates a substrate processing apparatus according to the fourth embodiment of the present invention; and

FIG. 12 is a plane view illustrating a gas distribution area and a gas pumping area defined on a substrate supporter shown in FIG. 11.

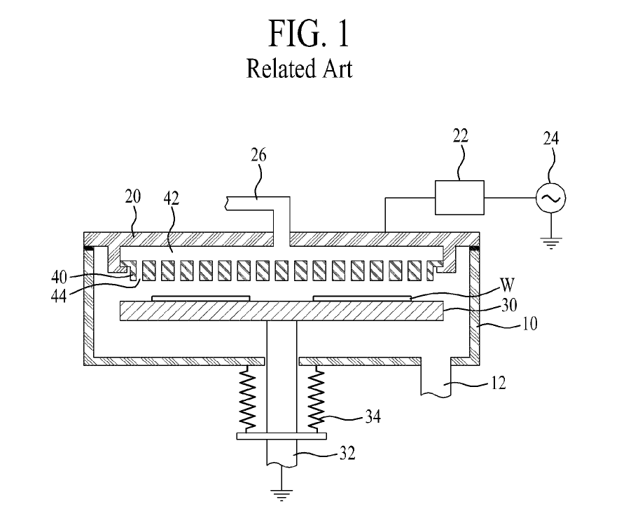

### DETAILED DESCRIPTION OF THE INVENTION

Hereinafter, embodiments of the present invention will be described in detail with reference to the accompanying drawings.

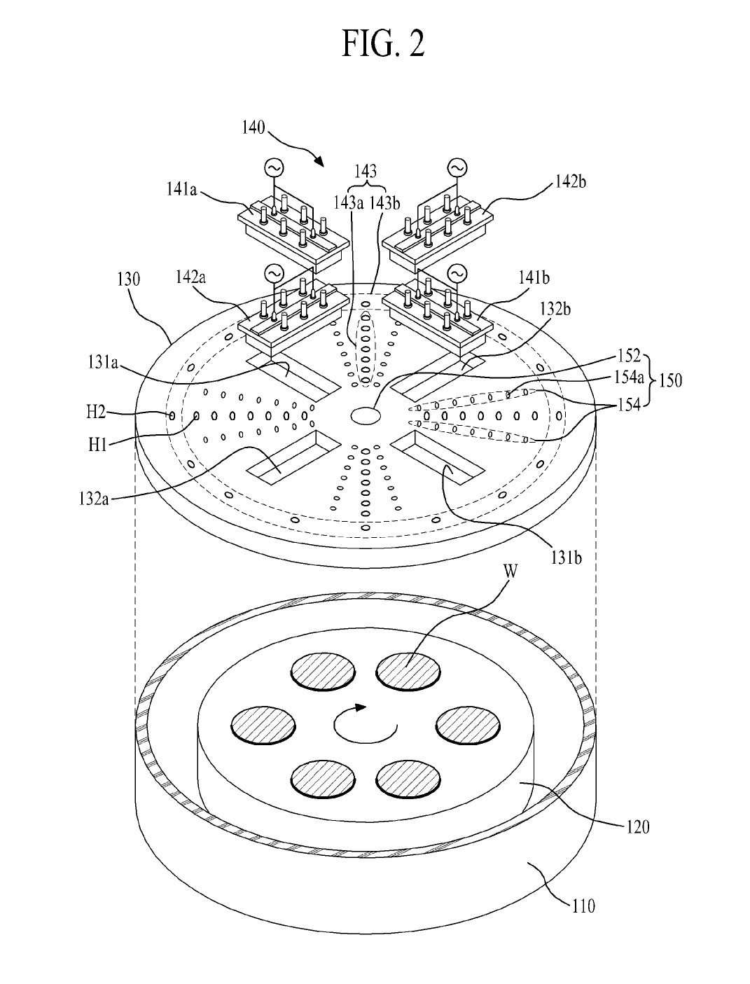

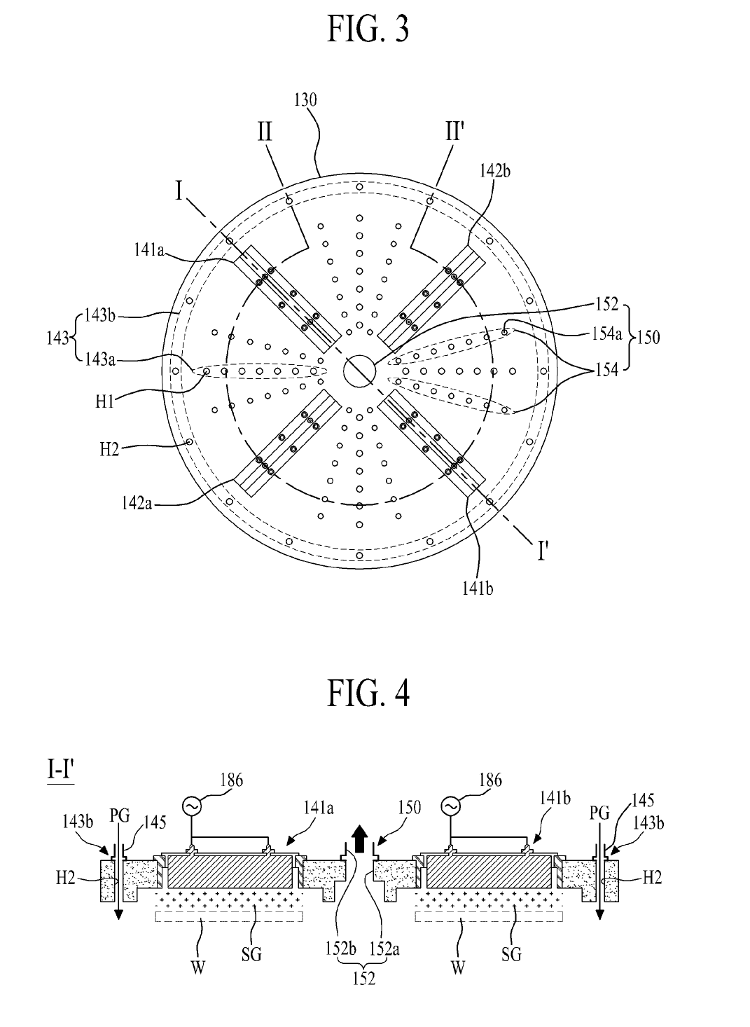

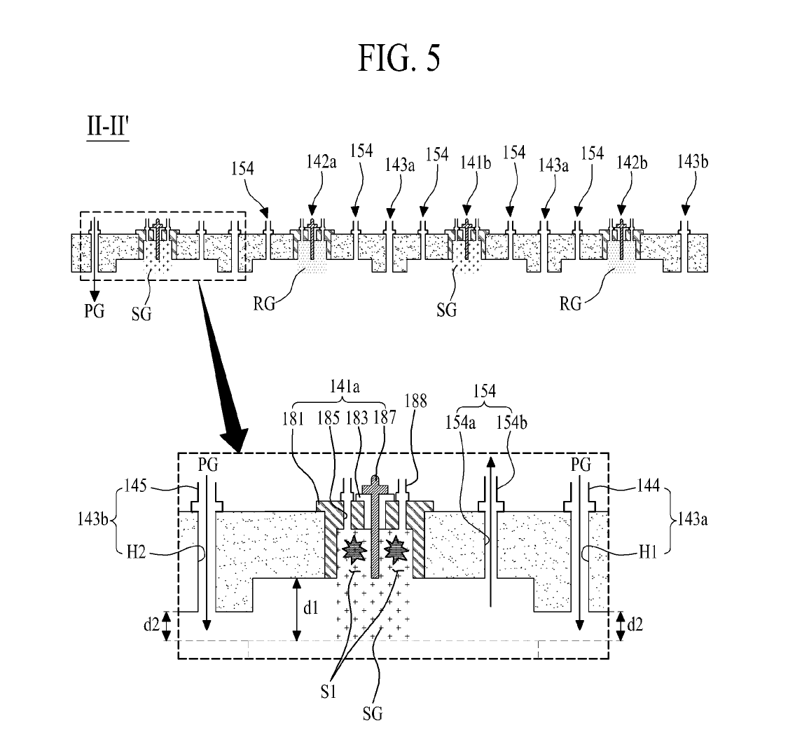

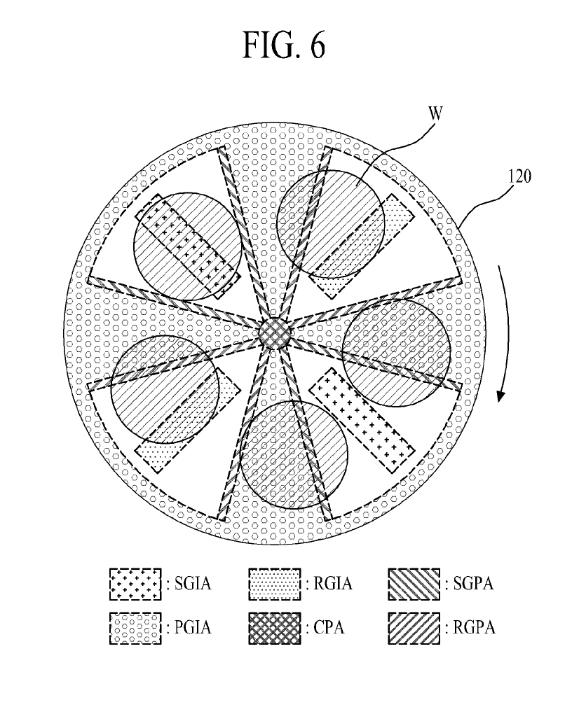

FIG. 2 is a perspective view illustrating a substrate processing apparatus according to the first embodiment of the present invention. FIG. 3 is a plane view illustrating a chamber lid shown in FIG. 2. FIG. 4 is a cross sectional view illustrating a chamber lid along I-I′ of FIG. 3. FIG. 5 is a cross sectional view illustrating a chamber lid along II-II′ of FIG. 3. FIG. 6 is a plane view illustrating a gas distribution area and a gas pumping area defined on a substrate supporter shown in FIG. 2.

Referring to FIGS. 2 to 6, the substrate processing apparatus according to the first embodiment of the present invention may include a process chamber 110; a substrate supporter 120 provided on the bottom of the process chamber 110, wherein the substrate supporter 120 supports at least one substrate (W) thereon; a chamber lid 130 for covering an upper side of the process chamber 110; a gas distributing part 140 for distributing source gas (SG), reactant gas (GS) and purge gas (PG) to different gas distribution areas on the substrate supporter 120, wherein the gas distributing part 140 is provided in the chamber lid 130; and a gas pumping part 150 for pumping gas surrounding the gas distribution areas to the outside, wherein the gas pumping part 150 is provided in the process chamber 130.

The process chamber 110 provides a reaction space for substrate processing, for example, a thin film deposition process. A bottom surface and/or a lateral surface of the process chamber 110 may be communicated with an exhaust pipe (not shown) for discharging gas from the reaction space.

The substrate supporter 120 is rotatably provided in the inner bottom of the process chamber 110. The substrate supporter 120 is supported by a rotation axis (not shown) penetrating through a central portion of the bottom surface of the process chamber 110, and the substrate supporter 120 may be electrically floating or grounded. In this case, the rotation axis exposed out of the bottom surface of the process chamber 100 is sealed by a bellows (not shown) provided in the bottom surface of the process chamber 110.

The substrate supporter 120 supports at least one substrate (W) loaded by an external substrate loading apparatus (not shown). The substrate supporter 120 may be formed in shape of a circular plate. The substrate (W) may be a semiconductor substrate or a wafer. In this case, it is preferable that the plurality of substrates (W) be arranged at fixed intervals in a circular pattern on the substrate supporter 120 so as to improve the yield.

According as the substrate supporter 120 is rotated to a predetermined direction (for example, clockwise direction) by rotation of the rotation axis, the substrate (W) is rotated and thus is moved in accordance with a predetermined order so that the substrate (W) is sequentially exposed to the source gas (SG), purge gas (PG) and reactant gas (RG). Accordingly, the substrate (W) is sequentially exposed to the source gas (SG), purge gas (PG) and reactant gas (RG) by rotation of the substrate supporter 120, whereby a single-layered or multi-layered thin film is deposited on the substrate (W) by ALD (Atomic Layer Deposition).

The chamber lid 130 is provided on the process chamber 110, that is, the chamber lid 130 covers the process chamber 110. The chamber lid 130 seals the reaction space prepared in the process chamber 110, and also supports the gas distributing part 140.

The gas distributing part 140 is inserted into the chamber lid 130. The gas distributing part 140 locally distributes the source gas (SG), reactant gas (RG) and purge gas (PG) to different gas distribution areas (SGIA, RGIA, PGIA) which are spatially separated from one another, wherein the source gas distribution area (SGIA) and the reactant gas distribution area (RGIA) are spatially separated from each other by distributing the purge gas (PG). Also, the gas distributing part 140 additionally distributes the purge gas (PG) to the circumference of the substrate supporter 120 corresponding to a space between an inner sidewall of the process chamber 110 and a lateral surface of the substrate supporter 120 so that it is possible to prevent an undesired thin film from being deposited on the inner sidewall of the process chamber 110 and the lateral surface of the substrate supporter 120 by reaction between the source gas (SG) and the reactant gas (RG). To this end, the gas distributing part 140 may include a pair of source gas distribution modules 141a and 141b, a pair of reactant gas distribution modules 142a and 142b, and a purge gas distribution module 143.

The source gas (SG) may be a gas including a thin film material to be deposited on the substrate (W). The source gas may include the thin film material of silicon (Si), titanium family element (Ti, Zr, Hf, and etc.), or aluminum (Al). For example, the source gas including the thin film material of silicon (Si) may be the gas selected from silane (SiH4), disilane (Si2H6), trisilane (Si3H8), TEOS (Tetraethylorthosilicate), DCS (Dichlorosilane), HCD (Hexachlorosilane), TriDMAS (Tri-dimethylaminosilane), TSA (Trisilylamine), and etc.

The reactant gas (RG) may be a gas which reacts with the source gas (SG) so as to make the thin film material included in the source gas (SG) be deposited on the substrate (W). For example, the reactant gas (RG) may be at least any one kind gas among hydrogen (H2), nitrogen (N2), oxygen (O2), nitrous oxide (N2O) and ozone (O3).

The purge gas (PG) may be an inert gas to purge the source gas (SG) being not deposited on the substrate (W) and/or the remaining reactant gas (RG), which does not reacts with the source gas (SG).

The pair of source gas distribution modules 141a and 141b may be provided in the chamber 130 in such a manner that the source gas distribution modules 141a and 141b included in the pair are symmetric to each other with respect to the center of the chamber lid 130. In this case, the source gas distribution modules 141a and 141b included in the pair are respectively inserted into a pair of first module receiving holes 131a and 131b formed in the chamber lid 130, and are combined with the chamber lid 130. The source gas distribution modules 141a and 141b included in the pair are respectively supplied with the source gas (SG) from an external gas supplying apparatus (not shown), and then downwardly distribute the source gas (SG) to the pair of source gas distribution areas (SGIA) defined on the substrate supporter 120. In this case, each of the source gas distribution modules 141a and 141b forms plasma in the inner space supplied with the source gas (SG), thereby activating (or making plasma) the source gas (SG), and distributing the activated source gas to the substrate (W). To this end, each of the source gas distribution modules 141a and 141b included in the pair may include a ground frame 181, an insulating member 183, a source gas supplying hole 185, and a plasma electrode member 187, as shown in FIGS. 4 and 5.

The ground frame 181 is formed to have a source gas distribution space (S1), and is inserted into the first module receiving holes 131a and 131b prepared in the chamber lid 130. That is, the ground frame 181 comprises an upper plate combined with the upper surface of the chamber lid 130, and a ground sidewall downwardly protruding from the lower edge of the upper plate so as to prepare the source gas distribution space (S1) having a predetermined size. The ground frame 181 is electrically connected with the chamber lid 130, and is electrically grounded by the chamber lid 130. Thus, the ground sidewall functions as a ground electrode in opposite to the plasma electrode member 187.

Preferably, a height of the ground sidewall may be the same as a height of the first module receiving holes 131a and 131b, or may be smaller than a thickness of the chamber lid 130 so as to prevent the ground sidewall from protruding out of the lower surface of the chamber lid 130.

A first distance (d1) between the substrate (or substrate supporter 120) and the lower surface of the ground frame 181, that is, the lower surface of the ground sidewall may be determined within a range of 5 mm-50 mm. If the first distance (d1) between the substrate (W) and the lower surface of the ground sidewall is less than 5 mm, the substrate (W) may be damaged by the plasma occurring in the source gas distribution space (S1). Meanwhile, if the first distance (d1) between the substrate (W) and the lower surface of the ground sidewall is not less than 50 mm, deposition efficiency may be lowered due to recombination of the source gas activated and distributed by the plasma.

The insulating member 183 is formed of an insulating material (for example, ceramic material), wherein the insulating member 183 is inserted into an insulating member supporting hole formed in the ground frame 181 so that the ground frame 181 is electrically insulated from the plasma electrode member 187.

The source gas supplying hole 185 penetrates through the upper plate of the ground frame 181, and then the source gas supplying hole 185 is communicated with the source gas distribution space (S1). After the source gas supplying hole 185 is supplied with the source gas (SG) from the gas supplying apparatus through a source gas supplying pipe 188, the source gas (SG) supplied to the source gas supplying hole 185 is distributed to the source gas distribution space (S1).

The plasma electrode member 187 is formed of a conductive material. The plasma electrode member 187 is inserted into the source gas distribution space (S1) through an electrode insertion hole formed in the insulating member 183, and is arranged in parallel to the ground sidewall. Preferably, the lower surface of the plasma electrode member 187 is positioned at the same height as the lower surface of the ground sidewall, or is positioned inside the source gas distribution space (S1).

According as the plasma electrode member 187 is electrically connected with a plasma power supplier 186 by the use of feed cable, the plasma electrode member 187 generates the plasma in the source gas distribution space (S1) in accordance with plasma power supplied from the plasma power supplier 186 and the source gas (SG) supplied to the source gas distribution space (S1) through the source gas supplying hole 185, to thereby activate the source gas (SG). The activated source gas is downwardly distributed to the substrate (W) by a flux (or flow) of the source gas (SG) supplied to the source gas distribution space (S1), whereby the source gas distribution area (SGIA) is locally formed on the substrate supporter 120.

The pair of reactant gas distribution modules 142a and 142b may be provided in the chamber 130 in such a manner that the reactant gas distribution modules 142a and 142b included in the pair are symmetric to each other with respect to the center of the chamber lid 130. In this case, the reactant gas distribution modules 142a and 142b included in the pair are respectively inserted into a pair of second module receiving holes 132a and 132b formed in the chamber lid 130, and are combined with the chamber lid 130. The reactant gas distribution modules 142a and 142b included in the pair are respectively supplied with the reactant gas (RG) from the external gas supplying apparatus (not shown), and then downwardly distributes the reactant gas (RG) to the pair of reactant gas distribution areas (RGIA) defined on the substrate supporter 120. In this case, each of the reactant gas distribution modules 142a and 142b forms plasma in the inner space supplied with the reactant gas (RG), thereby activating (or making plasma) the reactant gas (RG), and distributing the activated reactant gas to the substrate (W). To this end, each of the reactant gas distribution modules 142a and 142b included in the pair may include a ground frame having a reactant gas distribution space, an insulating member, a reactant gas supplying hole for supplying the reactant gas (RG) to the reactant gas distribution space, and a plasma electrode member for forming plasma in the reactant gas distribution space and activating the reactant gas (RG) by the use of plasma. These structures are the same as those for each of the source gas distribution modules 141a and 141b constituting the pair, whereby a detailed explanation for the same structures will be substituted by the above description.

The purge gas distribution module 143 is formed in the chamber lid 130, and more particularly, arranged between each source gas distribution module 141a and 141b and each reactant gas distribution module 142a and 142b. Also, the purge gas distribution module 143 is formed in the margin of the chamber lid 130 while being overlapped with the space between the inner sidewall of the process chamber 110 and the lateral surface of the substrate supporter 120. The purge gas distribution module 143 downwardly distributes the purge gas (PG) to the space between each source gas distribution module 141a and 141b and each reactant gas distribution module 142a and 142b, to thereby spatially separate the source gas distribution area (SGIA) and the reactant gas distribution area (RGIA) from each other. Also, the purge gas distribution module 143 downwardly distributes the purge gas (PG) to the space between the inner sidewall of the process chamber 110 and the lateral surface of the substrate supporter 120 so as to prevent the undesired thin film from being deposited on the inner sidewall of the process chamber 110 and the lateral surface of the substrate supporter 120 by reaction between the source gas (SG) and the reactant gas (RG) in the circumference of the substrate supporter 120. To this end, the purge gas distribution module 143 may include a plurality of first purge gas distribution members 143a, and a second purge distribution member 143b.

Each of the first purge gas distribution members 143a is formed in the chamber lid 130, and more particularly, arranged between each source gas distribution module 141a and 141b and each reactant gas distribution module 142a and 142b. Each of the first purge gas distribution members 143a downwardly distributes the purge gas (PG) which is supplied from the external gas supplying apparatus, to thereby form the purge gas distribution area (PGIA) between the source gas distribution area (SGIA) and the reactant gas distribution area (RGIA). That is, each of the first purge gas distribution members 143a forms an air curtain with the purge gas (PG) between the source gas distribution area (SGIA) and the reactant gas distribution area (RGIA), thereby spatially separating the source gas distribution area (SGIA) and the reactant gas distribution area (RGIA) from each other, and preventing a mixture of the source gas (SG) and the reactant gas (RG) distributed to the substrate supporter 120. To this end, each of the plurality of first purge gas distribution members 143a may include a plurality of first purge gas distribution holes (H1) and a plurality of first purge gas supplying pipes 144.

Each of the first purge gas distribution holes (H1) penetrates through the chamber lid 130. The plurality of first purge gas distribution holes (H1) are arranged at fixed intervals between the adjacent source gas distribution module 141a and 141b and the adjacent reactant gas distribution module 142a and 142b. In this case, a diameter in each of the plurality of first purge gas distribution holes (H1) and/or an interval between each of the first purge gas distribution holes (H1) may be gradually increased in a direction from the central portion of the chamber lid 130 to the edge of the chamber lid 130. The plurality of first purge gas distribution holes (H1) downwardly distribute the purge gas (PG) supplied from the gas supplying apparatus, to thereby form the plurality of purge gas distribution areas (PGIA) on the substrate supporter 120.

The lower surface of each of the first purge gas distribution holes (H1) is positioned relatively adjacent to the substrate (W) or substrate supporter 120. For example, a second distance (d2) between each of the first purge gas distribution holes (H1) and the substrate (W) is relatively smaller than the aforementioned first distance (d1) between source gas distribution module 141a and 141b and the substrate (W) or between the reactant gas distribution module 142a and 142b and the substrate (W). Accordingly, the purge gas (PG) distributed from each of the first purge gas distribution holes (H1) forms the purge gas distribution area (PGIA) on the substrate supporter 120, to thereby spatially separate the source gas distribution area (SGIA) and the reactant gas distribution area (RGIA) from each other, and purge the source gas (SG) which is not deposited on the substrate (W) and/or the reactant gas (RG) which does not react with the source gas (SG).

The plurality of first purge gas supplying pipes 144 are connected with the gas supplying apparatus for supplying the purge gas (PG), and are also respectively connected with the plurality of first purge gas distribution holes (H1).

The plurality of first purge gas distribution members 143a may include a first purge gas supplying module (not shown) provided in the chamber lid 130 so as to cover the plurality of first purge gas distribution holes (H1) instead of the plurality of first purge gas supplying pipes 144. After the first purge gas supplying module is supplied with the purge gas (PG) from the gas supplying apparatus, the first purge gas supplying module internally diffuses the purge gas (PG), and thus the diffused purge gas is supplied to the plurality of first purge gas distribution holes (H1). In this case, the plurality of first purge gas distribution members 143a may include at least one slit covered by the first purge gas supplying module, instead of the plurality of first purge gas distribution holes (H1).

The second purge gas distribution member 143b is formed in the margin of the chamber lid 130. The second purge gas distribution member 143b downwardly distributes the purge gas (PG), which is supplied from the gas supplying apparatus, to the space between the inner sidewall of the process chamber 110 and the lateral surface of the substrate supporter 120 so that it is possible to prevent the undesired thin film from being deposited on the inner sidewall of the process chamber 110 and the lateral surface of the substrate supporter 120 by reaction between the source gas (SG) and the reactant gas (RG) in the circumference of the substrate supporter 120. To this end, the second purge gas distribution member 143b may include a plurality of second purge gas distribution holes (H2) and a plurality of second purge gas supplying pipes 145.

Each of the second purge gas distribution holes (H2) penetrates through the chamber lid 130. The plurality of second purge gas distribution holes (H2) are arranged at fixed intervals along the margin of the chamber lid 130, and are also overlapped with the space between the inner sidewall of the process chamber 110 and the lateral surface of the substrate supporter 120. The plurality of second purge gas distribution holes (H2) downwardly distribute the purge gas (PG), which is supplied from the gas supplying apparatus through the plurality of second purge gas supplying pipes 145, to the circumference of the substrate supporter 120.

In the same manner as the plurality of first purge gas distribution holes (H1), the plurality of second purge gas distribution holes (H2) are positioned relatively adjacent to the substrate (W) or substrate supporter 120. Accordingly, the purge gas (PG) distributed from each of the second purge gas distribution holes (H2) forms the purge gas distribution area (PGIA) in the circumference of the substrate supporter 120 so that it is possible to prevent the source gas (SG) and the reactant gas (RG) respectively distributed from the source gas distribution modules 141a and 141b and the reactant gas distribution modules 142a and 142b from proceeding toward the inner sidewall of the process chamber 110. The source gas (SG), reactant gas (RG) and purge gas (PG) provided in the circumference of the substrate supporter 120 may be pumped to the outside through an exhaust hole prepared in the edge of the bottom surface of the process chamber 110.

The plurality of second purge gas supplying pipes 145 are connected with the gas supplying apparatus for supplying the purge gas (PG), and are also respectively connected with the plurality of second purge gas distribution holes (H2).

The plurality of second purge gas distribution members 143b may include a second purge gas supplying module (not shown) provided in the chamber lid 130 so as to cover the plurality of second purge gas distribution holes (H2) instead of the plurality of second purge gas supplying pipes 145. After the second purge gas supplying module, which is formed in a circular band shape, is supplied with the purge gas (PG) from the gas supplying apparatus, the second purge gas supplying module internally diffuses the purge gas (PG), and thus the diffused purge gas is supplied to the plurality of second purge gas distribution holes (H2). In this case, the plurality of second purge gas distribution members 143b may include a plurality of slits provided at fixed intervals and covered by the second purge gas supplying module instead of the plurality of second purge gas distribution holes (H2).

The gas pumping part 150 is provided in the chamber lid 130, and is overlapped with both sides of each of the source gas distribution area (SGIA) and the reactant gas distribution area (RGIA), to thereby pump the gas remaining around the gas distribution areas (SGIA, RGIA) to the outside of the process chamber 110. Also, the gas pumping part 150 is provided in the center of the chamber lid 130 so as to pump the gas remaining above the center of the substrate supporter 120 to the outside of the process chamber 110. To this end, the gas pumping part 150 may include a first gas pumping member 152 and a second gas pumping member 154.

The first gas pumping member 152 is provided in the center of the chamber lid 130 so as to pump the gas remaining in a central pumping area (CPA) defined in the center of the substrate supporter 120 to the outside. To this end, the first gas pumping member 152 may include a first pumping hole 152a and a first pumping pipe 152b, as shown in FIG. 4.

The first pumping hole 152a penetrating through the center of the chamber lid 130 is communicated with the center of the substrate supporter 120.

The first pumping pipe 152b is connected with the center of the chamber lid 130, and thus is communicated with the first pumping hole 152a. Also, the first pumping pipe 152 is connected with a gas exhaust apparatus (not shown). According as the gas exhaust apparatus is driven, the first pumping pipe 152b sucks the gas remaining in the central pumping area (CPA) through the first pumping hole 152a, and then discharges the gas to the outside.

The second gas pumping member 154 is provided in the chamber lid 130, wherein the second gas pumping member 154 is positioned adjacent to both sides of each of the source gas distribution module 141a and 141b and the reactant gas distribution module 142a and 142b. The second gas pumping member 154 separately pumps the source gas (SG) or unreacted source gas in source gas pumping areas (SGPA) defined in both sides of the source gas distribution area (SGIA), and the reactant gas (RG) or unreacted reactant gas in reactant gas pumping areas (RGPA) defined in both sides of the reactant gas distribution area (RGIA). That is, the second gas pumping member 154 separately pumps the source gas (SG) and the reactant gas (RG) so that it is possible to prevent powder caused by mixture of the source gas (SG) and the reactant gas (RG), thereby extending an overhaul period of the gas exhaust apparatus, that is, pump. To this end, the second gas pumping member 154 may include a plurality of second pumping holes 154a and a plurality of second pumping pipes 154b, as shown in FIG. 5.

The plurality of second pumping holes 154a are formed at fixed intervals so as to penetrate through the chamber lid 130 adjacent to both sides of each of the source gas distribution module 141a and 141b and the reactant gas distribution module 142a and 142b or both sides of the first purge gas distribution member 143a. In this case, a diameter in each of the plurality of second pumping holes 154a and/or an interval between each of the second pumping holes 154a may be gradually increased in a direction from the central portion of the chamber lid 130 to the edge of the chamber lid 130.

The plurality of second pumping holes 154a provided at both sides of the source gas distribution module 141a and 141b pump the source gas (SG) of the source gas pumping area (SGPA), and the plurality of second pumping holes 154a provided at both sides of the reactant gas distribution module 142a and 142b pump the reactant gas (RG) of the reactant gas pumping area (RGPA). Meanwhile, the purge gas (PG), which is distributed to the purge gas distribution area (PGIA) by the purge gas distribution module 144, may be pumped together with the source gas (SG) or reactant gas (RG) to the outside of the process chamber 110 by the plurality of second pumping holes 154a.

The lower surface of the plurality of second pumping holes 154a is provided at the first distance (d1) from the substrate (W) or substrate supporter 120. Accordingly, a stepped portion is prepared between the lower surface of the plurality of second pumping holes 154a and each of the first and second purge gas distribution holes (H1, H2) of the aforementioned purge gas distribution module 143. This stepped portion prevents the source gas (SG) and reactant gas (RG) distributed to the substrate (W) from proceeding toward the purge gas distribution area (PGIA), whereby the plurality of second pumping holes 154a smoothly suck the source gas (SG) and reactant gas (RG) distributed to the substrate (W). In the drawings, the stepped portion is formed between the lower surface of the plurality of second pumping holes 154a and each of the first and second purge gas distribution holes (H1, H2), but it is not limited to this structure. For example, the lower surface of the plurality of second pumping holes 154a may be positioned at the same height as the lower surface of the first and second purge gas distribution holes (H1, H2).

The plurality of second pumping pipes 154b are respectively connected with the chamber lid 130 so that the plurality of second pumping pipes 154b are communicated with the chamber lid 130. Also, the plurality of second pumping pipes 154b are connected with the gas exhaust apparatus. According as the gas exhaust apparatus is driven, the plurality of second pumping pipes 154b suck the source gas of the source gas pumping area (SGPA) through the plurality of second pumping holes 154a and then discharge the source gas to the outside, and suck the reactant gas of the reactant gas pumping area (RGPA) and then discharges the reactant gas to the outside.

The second gas pumping member 154 may include a gas pumping module (not shown) provided in the chamber lid 130 so as to cover the plurality of second pumping holes 154a instead of the plurality of second pumping pipes 154b. The gas pumping module is connected with the gas exhaust apparatus through one gas pumping pipe. According as the gas exhaust apparatus is driven, the gas pumping module sucks the gas of the gas pumping area to the inner space through the plurality of second pumping holes 154a, and then discharges the sucked gas to the gas exhaust apparatus through one gas pumping pipe. In this case, the second gas pumping member 154 may include at least one pumping slit, which is covered by the gas pumping module, instead of the plurality of second pumping holes 154a.

A substrate processing method using the substrate processing apparatus according to the first embodiment of the present invention will be described with reference to FIGS. 2 to 6.

First, the plurality of substrates (W) are loaded at fixed intervals onto the substrate supporter 120, and are placed thereon.

Then, the activated source gas, the activated reactant gas and the purge gas may be downwardly distributed to the substrate supporter 120 through the gas distributing part 140, and locally deposited onto the substrate supporter 120. That is, the plasma power and the source gas (SG) are supplied to the pair of source gas distribution modules 141a and 141b, whereby the activated source gas is downwardly distributed to the substrate supporter 120. Also, the plasma power and the reactant gas (RG) are supplied to the pair of reactant gas distribution modules 142a and 142b, whereby the activated reactant gas is downwardly distributed to the substrate supporter 120. Also, the purge gas (PG) is supplied to the purge gas distribution module 143, whereby the purge gas is downwardly distributed to the substrate supporter 120. In this case, the source gas (SG) and the reactant gas (RG) may be simultaneously or sequentially distributed in accordance with a processing order preset by a thin film deposition process.

On the substrate supporter 120, there are the plurality of source gas distribution areas (SGIA) to which the source gas is distributed, the plurality of reactant gas distribution area (RGIA) to which the reactant gas is distributed, and the purge gas distribution area (PGIA) to which the purge gas is distributed.

According as the gas pumping part 150 is driven, the gases of the central pumping area (CPA), source gas pumping area (SGPA) and reactant gas pumping area (RGPA) are separately pumped. Thus, the activated source gas distributed to the plurality of source gas distribution areas (SGIA) is spatially separated from the activated reactant gas distributed to the plurality of reactant gas distribution areas (RGIA) by the purge gas distribution area (PGIA), and the source gas (SG) and the reactant gas (RG) are separately pumped to the outside by the use of gas pumping part 150, whereby the source gas (SG) and the reactant gas (RG) are not mixed together while being distributed to the substrate supporter 120.

Then, the substrate supporter 120 onto which the plurality of substrates (W) are loaded is rotated to the predetermined direction (for example, clockwise direction). Accordingly, while the substrate (W) sequentially passes through the source gas distribution area (SGIA), the purge gas distribution area (PGIA), the reactant gas distribution area (RGIA) and the purge gas distribution area (PGIA), the substrate (W) is sequentially exposed to the activated source gas, the purge gas, the activated reactant gas and the purge gas, whereby the predetermined thin film material is deposited on the substrate (W) by the reaction of the activated source gas and the activated reactant gas.

The substrate processing apparatus and method according to the first embodiment of the present invention enables to prevent the substrate (W) from being exposed to the plasma by activating the source gas (SG) and reactant gas (RG) through the high-density plasma formed in the gas distribution space prepared inside the gas distribution module, and distributing the activated source gas and reactant gas to the substrate (W), to thereby prevent the substrate (W) from being damaged. Unlike the related art, the first embodiment of the present invention discloses that the plasma discharging space is formed in the space between the plasma electrode and the ground electrode confronting each other, instead of the space between the plasma electrode and the substrate (W). According to the present invention, the plasma discharging space is not overlapped with the substrate formation region supported by the substrate supporter 120 so that it is possible to prevent the substrate (W) from being damaged by the plasma discharge, and to prevent the quality of thin film deposited on the substrate (W) from being deteriorated.

In the substrate processing apparatus and method according to the first embodiment of the present invention, the thin film is formed by ALD (Atomic Layer Deposition) which spatially separates the source gas (SG) and the reactant gas (RG) distributed to the substrate supporter 120 from each other through the purge gas distribution, and sequentially exposes the substrate (W) to the separated source gas (SG) and reactant gas (RG) by rotating the substrate (W), to thereby improve deposition uniformity of the thin film deposited on the substrate (W), and improve the yield. In addition, the source gas (SG) and reactant gas (RG) may be spatially separated by the purge gas (PG) so that it is possible to prevent the undesired thin film from being deposited on the inner sidewall of the process chamber 110 and the lateral surface of the substrate supporter 120 except the upper surface of the substrate supporter 120 including the substrate (W), thereby extending In-Situ cleaning and wet cleaning cycle of the process chamber 110.

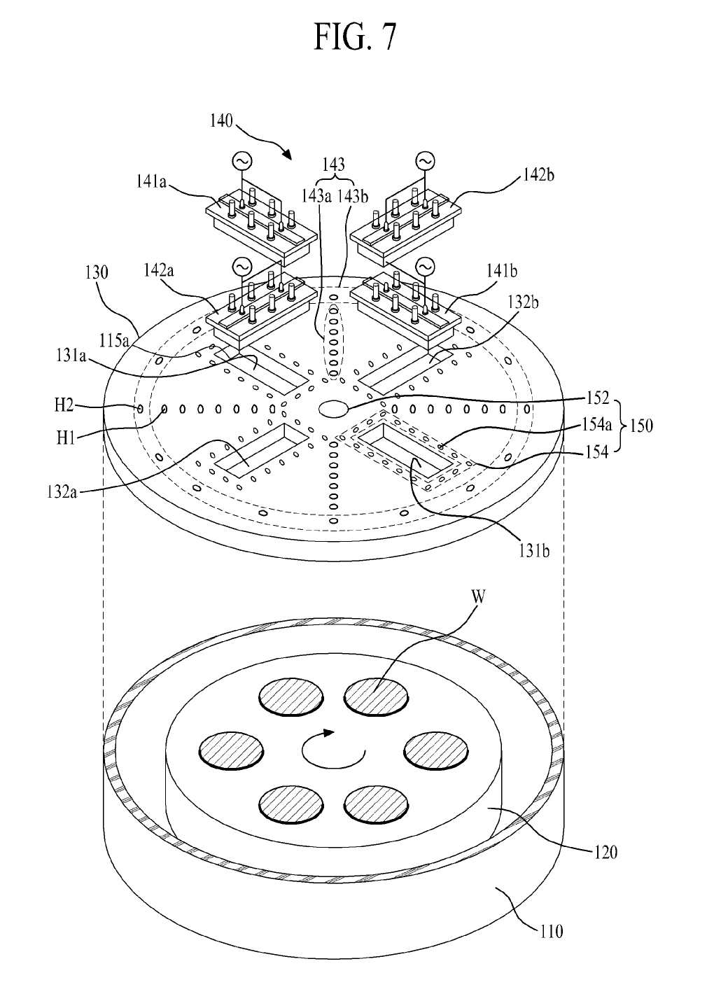

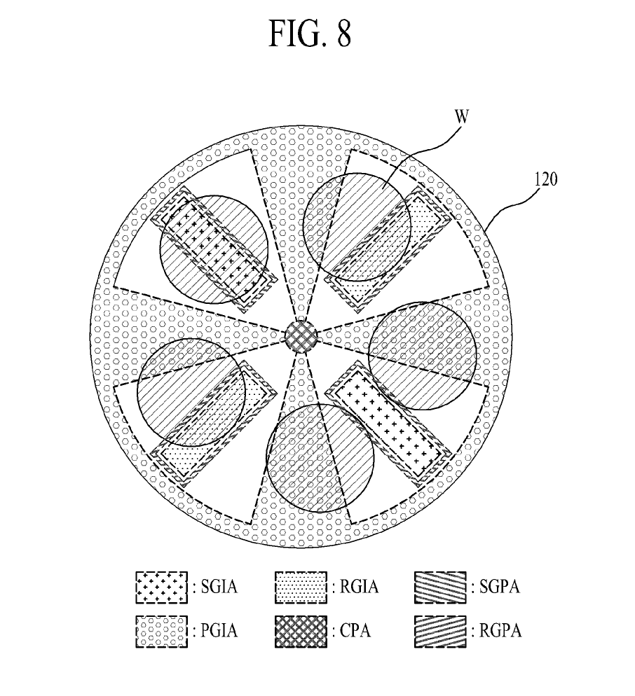

FIG. 7 illustrates a substrate processing apparatus according to the second embodiment of the present invention. FIG. 8 is a plane view illustrating a gas distribution area and a gas pumping area defined on a substrate supporter shown in FIG. 2. Except a structure of a gas pumping part 150, the substrate processing apparatus according to the second embodiment of the present invention is identical in structure to the substrate processing apparatus according to the first embodiment of the present invention shown in FIGS. 2 to 6, whereby the same reference number will be used throughout the drawings to refer to the same or like parts, and a detailed explanation for the same parts will be omitted.

The gas pumping part 150 for covering source gas distribution area (SGIA) and reactant gas distribution area (GIA) is provided in a chamber lid 130, wherein the gas pumping part 150 pumps gas remaining in the space for covering the gas distribution areas (SGIA, RGIA) to the outside of a process chamber 110. Also, the gas pumping part 150 is formed in the center of the chamber lid 130 so as to pump the gas remaining above the center of a substrate supporter 120 to the outside of the process chamber 110. To this end, the gas pumping part 150 may include a first gas pumping member 152 and a second gas pumping member 154.

The first gas pumping member 152 is provided in the center of the chamber lid 130, to thereby pump the gas of a central pumping area (CPA) defined in the center of the substrate supporter 120 to the outside. To this end, as shown in FIG. 4, the first gas pumping member 152 may include a first pumping hole 152a and a first pumping pipe 152b, wherein a detailed explanation for these elements will be substituted by the above description of FIG. 4.

The second gas pumping member 154 is provided in the chamber lid 130, wherein the second gas pumping member 154 is positioned to cover each source gas distribution module 141a and 141b and each reactant gas distribution module 142a and 142b of the aforementioned gas distributing part 140. The second gas pumping member 154 pumps the source gas (SG) or unreacted source gas in a source gas pumping area (SGPA) defined to cover the source gas distribution area (SGIA), and the reactant gas (RG) or unreacted reactant gas in a reactant gas pumping area (RGPA) defined to cover the reactant gas distribution area (RGIA) to the outside. To this end, the second pumping member 154 may include a plurality of second pumping holes 154a and a plurality of second pumping pipes (not shown). Except the plurality of second pumping holes 154a respectively cover the source gas distribution module 141a and 141b and the reactant gas distribution module 142a and 142b, the second gas pumping member 154 is identical in structure to that of the substrate processing apparatus according to the first embodiment of the present invention. Accordingly, the second gas pumping member 154 pumps the source gas (SG) of the source gas pumping area (SGPA) defined to cover the source gas distribution module 141a and 141b to the outside, and separately pumps the reactant gas (RG) of the reactant gas pumping area (RGPA) defined to cover the reactant gas distribution module 142a and 142b to the outside.

The second gas pumping member 154 may include a gas pumping module (not shown) provided in the chamber lid 130 so as to cover the plurality of second pumping holes 154a instead of the plurality of second pumping pipes. The gas pumping module is connected with the gas exhaust apparatus through one gas pumping pipe. According as the gas exhaust apparatus is driven, the gas pumping module sucks the gas of the gas pumping area to the inner space through the plurality of second pumping holes 154a, and then discharges the sucked gas to the gas exhaust apparatus through one gas pumping pipe. In this case, the second gas pumping member 154 may include at least one pumping slit, which is covered by the gas pumping module, instead of the plurality of second pumping holes 154a.

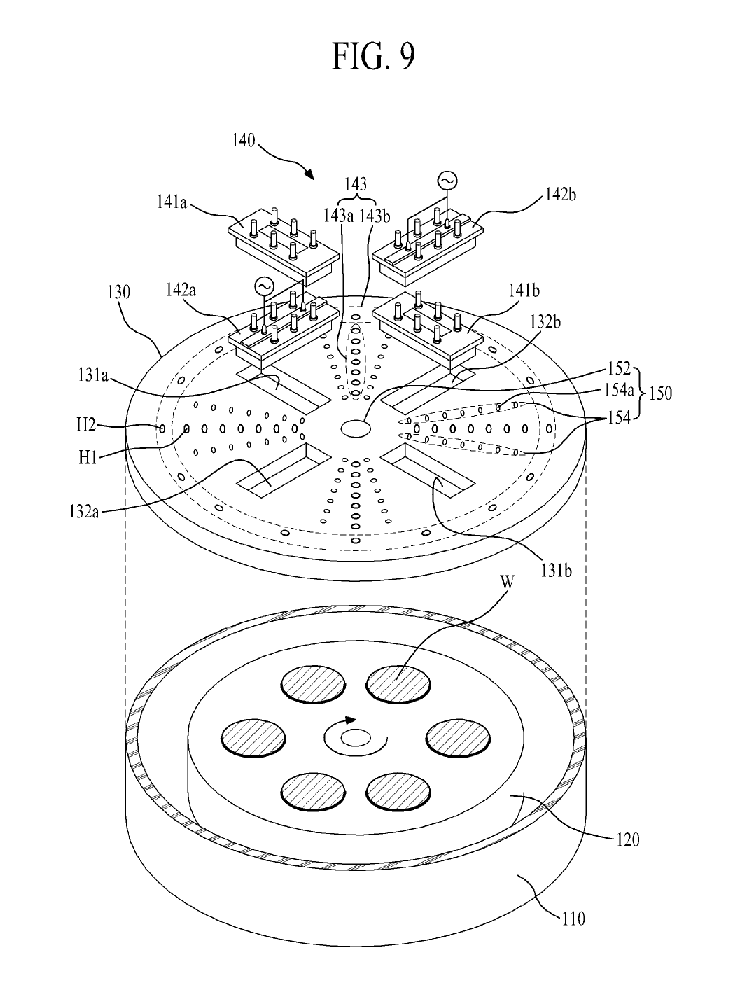

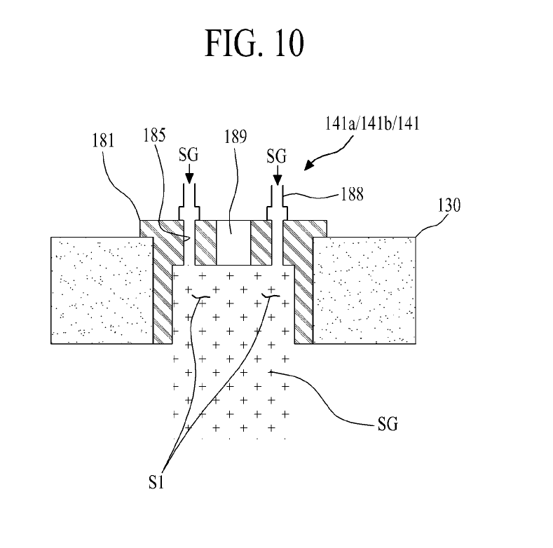

FIG. 9 illustrates a substrate processing apparatus according to the third embodiment of the present invention. FIG. 10 is a cross sectional view illustrating a pair of source gas distribution modules shown in FIG. 9.

Referring to FIGS. 9 and 10, the substrate processing apparatus according to the third embodiment of the present invention may include a process chamber 110, a substrate supporter 120, a chamber lid 130, a gas distributing part 140 and a gas pumping part 150. Except the gas distributing part 140, the substrate processing apparatus according to the third embodiment of the present invention is identical in structure to the substrate processing apparatus according to the first or second embodiment of the present invention, whereby the same reference number will be used throughout the drawings to refer to the same or like parts, and a detailed explanation for the same parts will be omitted.

Except that source gas (SG) supplied from an external gas supplying apparatus is not activated, and is distributed to a substrate supporter 120, the gas distributing part 140 of the third embodiment of the present invention is identical to that of the first or second embodiment of the present invention. Accordingly, only a pair of source gas distribution modules 141a and 141b for distributing the source gas (SG) will be described in detail, and a detailed explanation for the other elements will be substituted by the above description of the first or second embodiment of the present invention.

As shown in FIG. 10, each of the source gas distribution modules 141a and 141b constituting the pair may include a ground frame 181, a source gas supplying hole 185 and a view port 189.

The ground frame 181 is formed to have a source gas distribution space (S1), and the ground frame 181 is inserted into a first module receiving holes 131a and 131b prepared in the chamber lid 130. That is, the ground frame 181 may comprise an upper plate combined with the upper surface of the chamber lid 130, and a ground sidewall downwardly protruding from the lower edge of the upper plate so as to prepare the source gas distribution space (S1) having a predetermined size.

The source gas supplying hole 185 penetrating through the upper plate of the ground frame 181 is communicated with the source gas distribution space (S1). After the source gas supplying hole 185 is supplied with the source gas (SG) from the gas supplying apparatus through a source gas supplying pipe 188, the source gas supplying hole 185 distributes the supplied source gas (SG) to the source gas distribution space (S1). Accordingly, the source gas (SG) distributed to the source gas distribution space (S1) is downwardly distributed to the aforementioned source gas distribution area.

The view port 189 is formed in the upper plate of the ground frame 181 so as to monitor the inside of the process chamber 110. That is, the view port 189 corresponds to a transparent window enabling a worker to watch the inside of the process chamber 110 so as to monitor a processing state.

The substrate processing apparatus according to the third embodiment of the present invention may further include a chamber monitoring means (not shown) provided outside the view port 189 in each of source gas distribution modules 141a and 141b. The chamber monitoring means may include a photograph means for photographing the thin film deposited on the substrate (W) through the use of view port 189. Accordingly, the worker monitors the processing state through the image of thin film photographed by the chamber monitoring means.

The substrate processing apparatus according to the third embodiment of the present invention may be applied to form the thin film of a silicon material on the substrate (W). That is, the source gas (SG) including the silicon material reacts with the reactant gas (RG) under the condition that the source gas (SG) is not activated. Meanwhile, on assumption that the thin film is deposited by the use of source gas (SG) of inactive state, as shown in the above embodiments of the present invention, if the source gas (SG) is activated by the plasma, and is then distributed to the substrate (W), it is possible to lower a processing temperature.

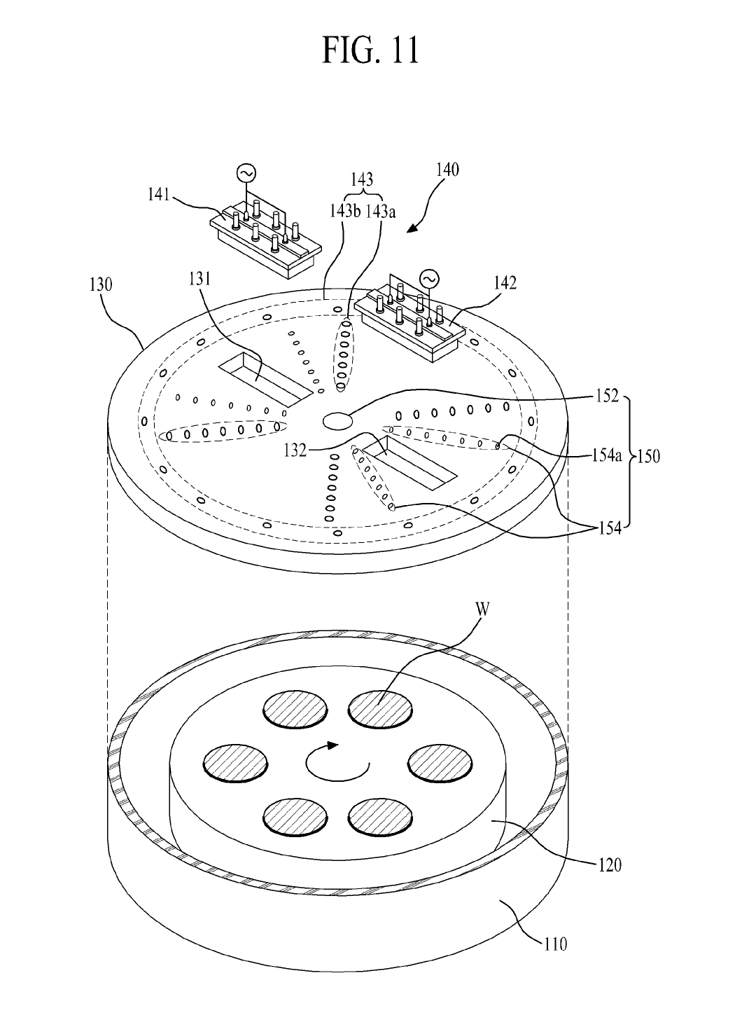

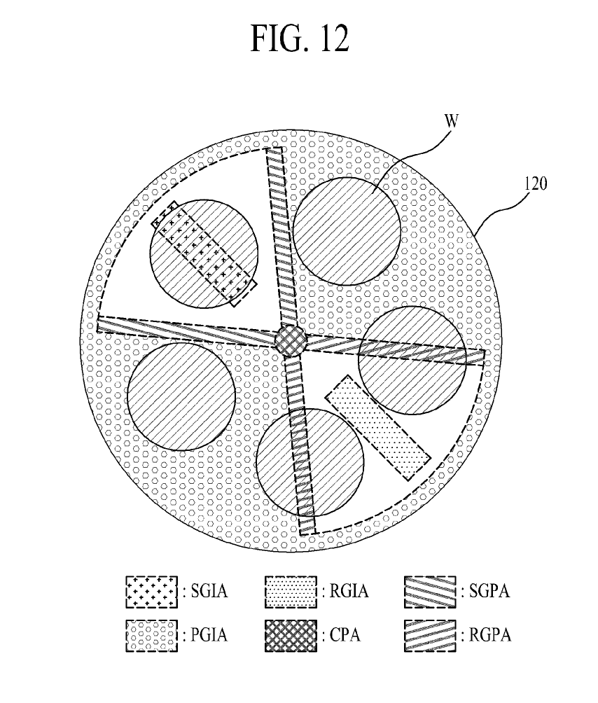

FIG. 11 illustrates a substrate processing apparatus according to the fourth embodiment of the present invention. FIG. 12 is a plane view illustrating a gas distribution area and a gas pumping area defined on a substrate supporter shown in FIG. 11.

Referring to FIGS. 11 and 12, the substrate processing apparatus according to the fourth embodiment of the present invention may include a process chamber 110, a substrate supporter 120, a chamber lid 130, a gas distributing part 140 and a gas pumping part 150.

The process chamber 110, the substrate supporter 120 and the chamber lid 130 in the substrate processing apparatus according to the fourth embodiment of the present invention are the same as those in the substrate processing apparatus according to the first embodiment of the present invention shown in FIGS. 2 to 6, whereby the same reference number will be used throughout the drawings to refer to the same or like parts, and a detailed explanation for the same parts will be omitted.

The gas distributing part 140 is inserted into the chamber lid 130. The gas distributing part 140 separately distributes source gas (SG), reactant gas (RG) and purge gas (PG) to respective gas distribution areas (SGIA, RGIA, PGIA) which are spatially separated on the substrate supporter 120, and the gas distributing part 140 spatially separates the source gas distribution area (SGIA) and the reactant gas distribution area (RGIA) from each other by distribution of the purge gas (PG). Also, the gas distributing part 140 additionally distributes the purge gas (PG) to the circumference of the substrate supporter 120 corresponding to the space between an inner sidewall of the process chamber 110 and a lateral surface of the substrate supporter 120 so that it is possible to prevent an undesired thin film from being deposited on the inner sidewall of the process chamber 110 and the lateral surface of the substrate supporter 120 by reaction between the source gas (SG) and the reactant gas (RG). To this end, the gas distributing part 140 may include a source gas distribution module 141, a reactant gas distribution module 142, and a purge gas distribution module 143.

The source gas distribution module 141 is provided at one side of the chamber lid 130. In this case, the source gas distribution module 141 is inserted into a first module receiving hole 131 of the chamber lid 130, and thus combined with the chamber lid 130. Like the aforementioned source gas distribution module of the substrate processing apparatus according to the first embodiment of the present invention, the source gas distribution module 141 of the substrate processing apparatus according to the fourth embodiment of the present invention activates the source gas (SG) supplied from a gas supplying apparatus, and downwardly distributes the activated source gas (SG) to one source gas distribution area (SGIA) locally defined on the substrate supporter 120.

The source gas distribution module 141 according to one embodiment of the present invention, as shown in FIGS. 4 and 5, may include a ground frame 181, an insulating member 183, a source gas supplying hole 185, and a plasma electrode member 187. These elements are the same as those included in the source gas distribution module of the substrate processing apparatus according to the first embodiment of the present invention, whereby a detailed explanation for these elements will be substituted by the above description.

The source gas distribution module 141 according to another embodiment of the present invention, as shown in FIG. 10, may include a ground frame 181, a source gas supplying hole 185, and a view port 189. These elements are the same as those included in the source gas distribution module of the substrate processing apparatus according to the third embodiment of the present invention, whereby a detailed explanation for these elements will be substituted by the above description.

The reactant gas distribution module 142 is formed in the chamber lid 130, wherein the reactant gas distribution module 142 and the source gas distribution module 141 are symmetric to each other with respect to the center of the chamber lid 130. In this case, the source gas distribution module 141 is inserted into a second module receiving hole 132 of the chamber lid 130, and thus combined with the chamber lid 130. Like the aforementioned reactant gas distribution module of the substrate processing apparatus according to the first embodiment of the present invention, the reactant gas distribution module 142 of the substrate processing apparatus according to the fourth embodiment of the present invention activates the reactant gas (RG) supplied from the gas supplying apparatus, and downwardly distributes the activated reactant gas (RG) to one reactant gas distribution area (RGIA) locally defined on the substrate supporter 120. The reactant gas distribution module 142 may include a ground frame having a reactant gas distribution space, an insulating member, a reactant gas supplying hole for supplying the reactant gas (RG) to the reactant gas distribution space, and a plasma electrode member for forming plasma in the reactant gas distribution space and activating the reactant gas (RG) by the use of plasma. These elements are the same as those included in the source gas distribution module of the substrate processing apparatus according to the above embodiment of the present invention, whereby a detailed explanation for these elements will be substituted by the above description.

The purge gas distribution module 143 is formed in the chamber lid 130, and more particularly, arranged in parallel to both sides of the source gas distribution module 141 and both sides of the reactant gas distribution module 142. Also, the purge gas distribution module 143 is formed in the chamber lid 130, and more particularly, overlapped with the space between the inner sidewall of the process chamber 110 and the lateral surface of the substrate supporter 120. The purge gas distribution module 143 downwardly distributes the purge gas (PG) to both sides in each of the source gas distribution module 141a and 141b and the reactant gas distribution module 142a and 142b, and downwardly distributes the purge gas (PG) to the space between the inner sidewall of the process chamber 110 and the lateral surface of the substrate supporter 120 so that it is possible to spatially separate the source gas distribution area (SGIA) and the reactant gas distribution area (RGIA) from each other, and also to prevent an undesired thin film from being deposited on the inner sidewall of the process chamber 110 and the lateral surface of the substrate supporter 120 by reaction between the source gas (SG) and the reactant gas (RG) in the circumference of the substrate supporter 120. To this end, the purge gas distribution module 143 may include a plurality of first purge gas distribution members 143a, and a second purge gas distribution member 143b. Except the purge gas distribution module 143 is provided at both sides in each of one source gas distribution module 141 and one reactant gas distribution module 142, the purge gas distribution module 143 is identical in structure to that of the substrate processing apparatus according to the first embodiment of the present invention, whereby a detailed explanation for the same parts will be substituted by the above description.

The gas pumping part 150 is formed in the chamber lid 130, and more particularly, overlapped with the center of the substrate supporter 120. Also, the gas pumping part 150 is positioned adjacent to both sides in each of the source gas distribution module 141 and the reactant gas distribution module 142. The gas pumping part 150 pumps the gas of gas pumping areas (CPA, SGPA, RGPA) corresponding to the center of the substrate supporter 120 and the circumferential areas of gas distribution areas (SGIA, RGIA) to the outside of the process chamber 110, to thereby discharge the gas out of the above areas. To this end, the gas pumping part 150 may include first and second gas pumping members 152 and 154. Except that the gas pumping part 150 is provided at both sides in each of one source gas distribution module 141 and one reactant gas distribution module 142, the gas pumping part 150 is identical in structure to that of the substrate processing apparatus according to the first embodiment of the present invention, whereby a detailed explanation for the same parts will be substituted by the above description.

Meanwhile, the second gas pumping member 154 of the gas pumping part 150 may be formed to cover each of the source gas distribution module 141 and the reactant gas distribution module 142, as shown in FIGS. 7 and 8.

According to the substrate processing apparatus and method of the present invention, the thin film is formed on the substrate (W) by ALD (Atomic Layer Deposition) which spatially separates the source gas (SG) and the reactant gas (RG) from each other through the purge gas distribution, and sequentially exposes the substrate (W) to the separated source gas (SG) and reactant gas (RG) by rotating the substrate (W), to thereby improve deposition uniformity of the thin film deposited on the substrate (W), and improve the yield.

Also, the source gas (SG) and reactant gas (RG) may be spatially separated by the purge gas (PG) so that it is possible to prevent the undesired thin film from being deposited on the inner sidewall of the process chamber 110 and the lateral surface of the substrate supporter 120 except the upper surface of the substrate supporter 120 including the substrate (W), thereby extending In-Situ cleaning and wet cleaning cycle of the process chamber 110.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A substrate processing apparatus comprising:
a process chamber;
a substrate supporter for supporting at least one of substrates, wherein the substrate supporter is provided in the bottom of the process chamber;
a chamber lid confronting with the substrate supporter, the chamber lid for covering an upper side of the process chamber; and
a gas distributing part provided in the chamber lid, wherein the gas distributing part distributes source gas to a source gas distribution area on the substrate supporter, distributes reactant gas to a reactant gas distribution area which is separated from the source gas distribution area, and distributes purge gas to a space between the source gas distribution area and the reactant gas distribution area.

2. The apparatus of claim 1, wherein the gas distributing part additionally distributes the purge gas to a space between an inner sidewall of the process chamber and a lateral surface of the substrate supporter.

3. The apparatus of claim 1, wherein the gas distributing part includes:
at least one source gas distribution module, provided in the chamber lid, for distributing the source gas to the source gas distribution area;
at least one reactant gas distribution module, provided in the chamber lid, for distributing the reactant gas to the reactant gas distribution area; and
a purge gas distribution module, provided in the chamber lid, for distributing the purge gas to a purge gas distribution area between the source gas distribution area and the reactant gas distribution area.

4. The apparatus of claim 3, wherein each of the source gas distribution module and the reactant gas distribution module includes:
a ground frame having a ground sidewall for preparing a gas distribution space;
a gas supplying hole formed in the ground frame and communicated with the gas distribution space, wherein the gas supplying hole supplies the gas to the gas distribution space;
a plasma electrode member inserted into the gas distribution space and arranged in parallel to the ground sidewall, wherein the plasma electrode member forms plasma in the gas distribution space in accordance with plasma power, and activates the gas supplied to the gas distribution space by the use of plasma; and
an insulating member for electrically insulating the plasma electrode member and the ground frame from each other.

5. The apparatus of claim 3, wherein the source gas distribution module includes:
a ground frame having a ground sidewall for preparing a source gas distribution space; and
a gas supplying hole formed in the ground frame and communicated with the source gas distribution space, wherein the gas supplying hole supplies the source gas to the source gas distribution space.

6. The apparatus of claim 3, wherein the purge gas distribution module includes a plurality of first purge gas distribution member which have a plurality of first purge gas distribution holes for distributing the purge gas to the purge gas distribution area, wherein the plurality of purge gas distribution holes are formed in the chamber lid, and positioned adjacent to both sides in each of the source gas distribution module and the reactant gas distribution module.

7. The apparatus of claim 6, wherein the purge gas distribution module includes a second purge gas distribution member which has a plurality of second purge gas distribution holes for distributing the purge gas to the space between the inner sidewall of the process chamber and the lateral surface of the substrate supporter, wherein the plurality of second purge gas distribution holes are formed along the margin of the chamber lid.

8. The apparatus of claim 6, wherein the lower surface of each of the source gas distribution module and the reactant gas distribution module is provided at a first distance from the substrate supporter, and a second distance between the lower surface of the first purge gas distribution hole and the substrate supporter is smaller than the first distance.

9. The apparatus of claim 1, further comprising a gas pumping part, formed in the chamber lid, for separating the source gas in the circumference of the source gas distribution area from the reactant gas in the circumference of the reactant gas distribution area, and pumping the separated source gas and reactant gas out of the process chamber.

10. The apparatus of claim 9, wherein the gas pumping part includes a plurality of pumping holes formed in the chamber lid, wherein the plurality of pumping holes are positioned adjacent to both sides of each of the source gas distribution module and the reactant gas distribution module, or provided to cover the source gas distribution module and the reactant gas distribution module.

11. The apparatus of claim 9, wherein the gas pumping part pumps the gas staying above the center of the substrate supporter to the outside of the process chamber.

12. A substrate processing apparatus comprising:
a process chamber;
a substrate supporter for supporting at least one of substrates, wherein the substrate supporter is provided in the bottom of the process chamber;
a chamber lid confronting with the substrate supporter, the chamber lid for covering an upper side of the process chamber;
a gas distributing part for separately distributing source gas and reactant gas to different areas of the substrate supporter, wherein the gas distributing part is formed in the chamber lid; and
a gas pumping part for separating the source gas in the circumference of the source gas distribution area from the reactant gas in the circumference of the reactant gas distribution area, and pumping the separated source gas and reactant gas out of the process chamber, wherein the gas pumping part is formed in the chamber lid.

13. The apparatus of claim 12, wherein the gas distributing part includes:
at least one source gas distribution module, provided in the chamber lid, for distributing the source gas to the source gas distribution area; and
at least one reactant gas distribution module, provided in the chamber lid, for distributing the reactant gas to the reactant gas distribution area.

14. The apparatus of claim 12, wherein the gas pumping part includes a plurality of pumping holes formed in the chamber lid, wherein the plurality of pumping holes are positioned adjacent to both sides of each of the source gas distribution module and the reactant gas distribution module, or provided to cover the source gas distribution module and the reactant gas distribution module.

15. The apparatus of claim 1, wherein the gas distributing part activates and distributes at least any one kind of the source gas and the reactant gas.

16. A substrate processing method comprising:
loading at least one substrate onto a substrate supporter provided inside a process chamber;
distributing source gas to a source gas distribution area of the substrate supporter, distributing reactant gas to a reactant gas distribution area which is separated from the source gas distribution area, and distributing purge gas to a space between the source gas distribution area and the reactant gas distribution area; and
rotating the substrate supporter with at least one substrate loaded thereonto.

17. The method of claim 16, further comprising distributing the purge gas to a space between an inner sidewall of the process chamber and a lateral surface of the substrate supporter.

18. The method of claim 16, wherein the purge gas is distributed at a relatively short distance to the substrate supporter, in comparison to the source gas or reactant gas.

19. The method of claim 16, further comprising separating the source gas in the circumference of the source gas distribution area from the reactant gas in the circumference of the reactant gas distribution area, and pumping the separated source gas and reactant gas out of the process chamber.

20. The method of claim 19, further comprising pumping the gas staying above the center of the substrate supporter to the outside of the process chamber.

21. A substrate processing method comprising:
loading at least one substrate onto a substrate supporter provided inside a process chamber;
separately distributing source gas and reactant gas to different areas of the substrate supporter;
separating the source gas in the circumference of a source gas distribution area to be supplied with the source gas from reactant gas in the circumference of a reactant gas distribution area to be supplied with the reactant gas, and pumping the separated source gas and reactant gas out of the process chamber; and
rotating the substrate supporter with at least one substrate loaded thereonto.

22. The method of claim 21, wherein the source gas and the reactant gas are distributed simultaneously or sequentially.

23. The method of claim 21, wherein at least one kind of the source gas and the reactant gas is activated and distributed.
